(19) United States
(12) Patent Application Publication
(10) Pub. No.: US 2025/0336849 A1
(43) Pub. Date: Oct. 30, 2025

(54) SEMICONDUCTOR STRUCTURE AND SEMICONDUCTOR DEVICE

(71) Applicant: ENKRIS SEMICONDUCTOR, INC., Suzhou (CN)

(72) Inventor: Kai CHENG, Suzhou (CN)

(73) Assignee: ENKRIS SEMICONDUCTOR, INC., Suzhou (CN)

(21) Appl. No.: 18/737,535

(22) Filed: Jun. 7, 2024

(30) Foreign Application Priority Data
Apr. 30, 2024 (CN) 202410543519.8

(51) Int. Cl. H01L 23/64; H01L 29/16; H01L 29/20; H01L 29/78; H01L 29/868; H01L 29/872

(52) U.S. Cl. CPC H01L 23/647; H10D 8/50; H10D 8/60; H10D 30/615; H10D 62/8325; H10D 62/8503

(57) ABSTRACT

A semiconductor structure includes a SiC substrate, a heavily doped SiC layer, an AlGaN epitaxial layer, and a GaN epitaxial layer that are stacked sequentially. The GaN epitaxial layer includes a heavily doped layer and a lightly doped layer that are stacked, and the SiC substrate, the heavily doped SiC layer, the AlGaN epitaxial layer, and the GaN epitaxial layer are all of a first conductivity type. Design of the heavily doped SiC layer in the present disclosure is conducive to reducing on-resistance, so as to achieve a low turn-on voltage.

### CROSS-REFERENCE TO RELATED APPLICATIONS

The present disclosure claims priority to Chinese Patent Application 202410543519.8, filed on Apr. 30, 2024, the content of which is incorporated herein by reference in its entirety.

### TECHNICAL FIELD

The present disclosure relates to the field of semiconductor technologies, and in particular, to a semiconductor structure and a semiconductor device.

### BACKGROUND

Group III nitrides (such as GaN) have advantages such as a large band gap, a high electron mobility and a high breakdown field strength, which can meet operation requirements of next-generation power electronic systems for power devices with a relatively high power, a relatively high frequency, a relatively small size and a relatively high temperature, and therefore, devices made of the group III nitrides have become a hot research topic in new-generation power devices. There are many problems in conventional group III nitride devices, such as a low breakdown voltage and a large reverse leakage current, making it difficult to prepare high-quality and high-reliable group III nitride devices.

### SUMMARY

In view of this, the present embodiment provides a semiconductor structure and a semiconductor device to prepare high-quality and high-reliable group III nitride devices.

According to an aspect of the present disclosure, an embodiment of the present disclosure provides a semiconductor structure, including: a SiC substrate, a heavily doped SiC layer, an AlGaN epitaxial layer, and a GaN epitaxial layer that are stacked sequentially, the GaN epitaxial layer includes a heavily doped layer and a lightly doped layer that are stacked, and the SiC substrate, the heavily doped SiC layer, the AlGaN epitaxial layer, and the GaN epitaxial layer are all of a first conductivity type.

In an optional embodiment, the SiC substrate is a patterned substrate.

In an optional embodiment, on a side, close to the heavily doped SiC layer, of the SiC substrate, the SiC substrate includes a plurality of grooves partially penetrating the SiC substrate, and a variation trend of dimensions related to the plurality of grooves includes at least one of the followings: a periodic change in widths of the plurality of grooves or a periodic change in spacing distances between adjacent grooves in the plurality of grooves.

In an optional embodiment, on a side, close to the heavily doped SiC layer, of the SiC substrate, the SiC substrate includes a plurality of grooves partially penetrating the SiC substrate; a variation trend of dimensions related to the plurality of grooves includes at least one of the followings: widths of the plurality of grooves first gradually increasing and then gradually decreasing or spacing distances between adjacent grooves in the plurality of grooves first increasing and then gradually decreasing, and the dimensions related to the plurality of grooves increase from both sides to a middle, or a variation trend of dimensions related to the plurality of grooves includes at least one of the followings: widths of the plurality of grooves first gradually decreasing and then gradually increasing or spacing distances between adjacent grooves in the plurality of grooves first decreasing and then gradually increasing, and the dimensions related to the plurality of grooves decrease from both sides to a middle.

In an optional embodiment, the heavily doped SiC layer is conformally located on the SiC substrate.

In an optional embodiment, the heavily doped SiC layer is a patterned SiC layer, and on a side, away from the SiC substrate, of the heavily doped SiC layer, the heavily doped SiC layer includes a plurality of pits partially penetrating the heavily doped SiC layer.

In an optional embodiment, a variation trend of dimensions related to the plurality of pits includes at least one of the followings: a periodic change in widths of the plurality of pits or a periodic change in spacing distances between adjacent pits in the plurality of pits.

In an optional embodiment, a variation trend of dimensions related to the plurality of pits includes at least one of the followings: widths of the plurality of pits first gradually increasing and then gradually decreasing or spacing distances between adjacent pits in the plurality of pits first increasing and then gradually decreasing, and the dimensions related to the plurality of pits increase from both sides to a middle, or a variation trend of dimensions related to the plurality of pits includes at least one of the followings: widths of the plurality of pits first gradually decreasing and then gradually increasing or spacing distances between adjacent pits in the plurality of pits first decreasing and then gradually increasing, and the dimensions related to the plurality of pits decrease from both sides to a middle.

In an optional embodiment, the semiconductor structure further includes: a first insertion layer located between the heavily doped SiC layer and the AlGaN epitaxial layer, the first insertion layer is of a second conductivity type, and a tunnel junction is formed by the first insertion layer and the heavily doped SiC layer.

In an optional embodiment, a material of the first insertion layer includes SiC, and an nSiC/pSiC tunnel junction is formed by the heavily doped SiC layer and the first insertion layer.

In an optional embodiment, the semiconductor structure further includes: a second insertion layer located between the heavily doped SiC layer and the AlGaN epitaxial layer, the second insertion layer is of a second conductivity type, and a tunnel junction is formed by the second insertion layer and the AlGaN epitaxial layer.

In an optional embodiment, a material of the second insertion layer includes AlGaN, and a pAlGaN/nAlGaN tunnel junction is formed by the second insertion layer and the AlGaN epitaxial layer.

In an optional embodiment, an Al component of the second insertion layer decreases successively along a direction from the SiC substrate to the GaN epitaxial layer.

In an optional embodiment, the semiconductor structure further includes: a third insertion layer located between the AlGaN epitaxial layer and the GaN epitaxial layer, the third insertion layer is of a second conductivity type, and a tunnel junction is formed by the third insertion layer and the AlGaN epitaxial layer.

In an optional embodiment, a material of the third insertion layer includes AlGaN, and an nAlGaN/pAlGaN tunnel junction is formed by the AlGaN epitaxial layer and the third insertion layer.

In an optional embodiment, an Al component of the third insertion layer decreases successively along a direction from the SiC substrate to the GaN epitaxial layer.

According to another aspect of the present disclosure, an embodiment of the present disclosure provides a semiconductor device, including: the semiconductor structure described above, and the semiconductor device is any one of a Schottky diode, a Positive-Intrinsicnegative (PIN) diode, or a junction field effect transistor.

In an optional embodiment, in a case that the semiconductor device is the Schottky diode, the semiconductor device further includes a first electrode located on a side, away from the GaN epitaxial layer, of the SiC substrate and a second electrode located on a side, away from the SiC substrate, of the GaN epitaxial layer.

In an optional embodiment, in a case that the semiconductor device is the PIN diode, the semiconductor device further includes an intrinsic semiconductor layer, a second conductivity type semiconductor layer, a second electrode that are stacked sequentially on the GaN epitaxial layer, and a first electrode located on a side, away from the GaN epitaxial layer, of the SiC substrate.

In an optional embodiment, in a case that the semiconductor device is the junction field-effect transistor, the semiconductor device further includes a p-type region located within a surface, away from the SiC substrate, of the GaN epitaxial layer, a source located on a side, away from the SiC substrate, of the GaN epitaxial layer, a grid located on a side, away from the SiC substrate, of the p-type region, and a drain located on a side, away from the GaN epitaxial layer, of the SiC substrate.

### BRIEF DESCRIPTION OF THE DRAWINGS

FIG. 1 is a schematic structural diagram of a semiconductor structure according to an embodiment of the present disclosure.

FIG. 2 is a schematic structural diagram of a semiconductor structure according to an embodiment of the present disclosure.

FIG. 3 is a schematic structural diagram of a semiconductor structure according to an embodiment of the present disclosure.

FIG. 4 is a schematic structural diagram of a semiconductor structure according to an embodiment of the present disclosure.

FIG. 5 is a schematic structural diagram of a semiconductor structure according to an embodiment of the present disclosure.

FIG. 6 is a schematic structural diagram of a semiconductor structure according to an embodiment of the present disclosure.

FIG. 7 is a schematic structural diagram of a semiconductor structure according to an embodiment of the present disclosure.

FIG. 8 is a schematic structural diagram of a semiconductor structure according to an embodiment of the present disclosure.

FIG. 9 to FIG. 11 are schematic structural diagrams of semiconductor devices according to some embodiments of the present disclosure.

### DETAILED DESCRIPTIONS OF THE EMBODIMENTS

The following may provide a clear and complete description of technical solutions of the embodiments of the present disclosure in conjunction with the accompanying drawings of the embodiments of the present disclosure. Obviously, the described embodiments are only a part of the embodiments of the present disclosure, and not all of the embodiments. All other embodiments obtained by a person of ordinary skill in the art in the field based on the embodiments of the present disclosure without making creative labor fall within the scope of protection of the present disclosure.

In order to prepare a group III nitride device with high-quality and high-reliability, the present disclosure provides a semiconductor structure and a semiconductor device. The semiconductor structure includes a SiC substrate, a heavily doped SiC layer, an AlGaN epitaxial layer, and a GaN epitaxial layer that are stacked sequentially, the GaN epitaxial layer includes a heavily doped layer and a lightly doped layer that are stacked, and the SiC substrate, the heavily doped SiC layer, the AlGaN epitaxial layer, and the GaN epitaxial layer are all of a first conductivity type. On the one hand, design of the heavily doped SiC layer in the present disclosure is conducive to reducing on-resistance, so as to achieve a low turn-on voltage. Design of the patterned heavily doped SiC layer may further increase a contact area, so as to reduce on-resistance of an interface. On the other hand, a tunnel junction is formed by an insertion layer and one of the heavily doped SiC layer and the AlGaN epitaxial layer, and therefore, flow of charges may be effectively blocked by utilizing a tunnel mechanism to realize a normally-off characteristic of a semiconductor structure, which is beneficial for improving a threshold voltage and reducing a reverse leakage current. Design of the insertion layers in different epitaxial layers may regulate and control a position of the tunnel junction in a semiconductor structure, so as to further regulate a threshold voltage.

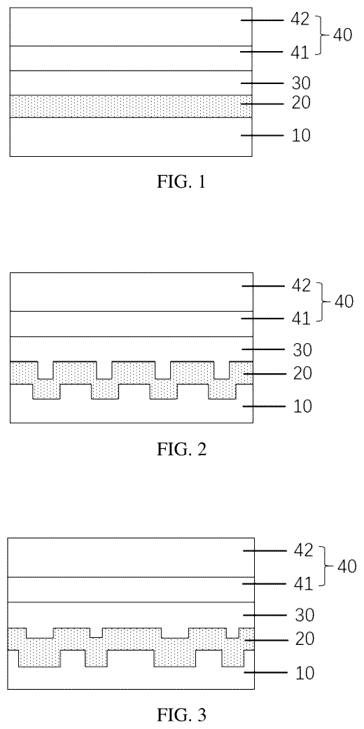

The following may further provide examples of a semiconductor structure and a semiconductor device mentioned in the present disclosure in conjunction with FIG. 1 to FIG. 11.

FIG. 1 is a schematic structural diagram of a semiconductor structure according to an embodiment of the present disclosure. As shown in FIG. 1, the semiconductor structure includes: a SiC substrate 10, a heavily doped SiC layer 20, an AlGaN epitaxial layer 30, and a GaN epitaxial layer 40 that are stacked sequentially. Along a direction away from the SiC substrate 10, the GaN epitaxial layer 40 includes a heavily doped layer 41 and a lightly doped layer 42 that are stacked. The SiC substrate 10, the heavily doped SiC layer 20, the AlGaN epitaxial layer 30, and the GaN epitaxial layer 40 are all of a first conductivity type. Design of the heavily doped SiC layer 20 is conducive to reducing on-resistance, so as to achieve a low turn-on voltage. In this embodiment, a doping concentration of an ion with the first conductivity type and in the AlGaN epitaxial layer 30 is greater than or equal to 1E18/cm³, a doping concentration of an ion with the first conductivity type and in the heavily doped layer 41 of the GaN epitaxial layer 40 is greater than or equal to 1E18/cm³, and a doping concentration of an ion with the first conductivity type and in the lightly doped layer 42 of the GaN epitaxial layer 40 is less than 1E18/cm³.

In an embodiment, FIG. 2 is a schematic structural diagram of a semiconductor structure according to an embodiment of the present disclosure. As shown in FIG. 2, the SiC substrate 10 is a patterned substrate, and the heavily doped SiC layer 20 is conformally located on the SiC substrate 10. Design of the patterned SiC substrate 10 and the patterned heavily doped SiC layer 20 may further increase a contact area between the SiC substrate 10 and the heavily doped SiC layer 20, as well as a contact area between the heavily doped SiC layer 20 and the AlGaN epitaxial layer 30, so as to reduce on-resistance of an interface, achieving a low turn-on voltage.

Optionally, FIG. 3 is a schematic structural diagram of a semiconductor structure according to an embodiment of the present disclosure. As shown in FIG. 3, on a side, close to the heavily doped SiC layer 20, of the SiC substrate 10, the SiC substrate 10 includes a plurality of grooves partially penetrating the SiC substrate 10, and a variation trend of dimensions related to the plurality of grooves may include at least one of the followings: a periodic change in widths of the plurality of grooves or a periodic change in spacing distances between adjacent grooves in the plurality of grooves. Since the heavily doped SiC layer 20 is conformally located on the SiC substrate 10, on a side, away from the SiC substrate 10, of the heavily doped SiC layer 20, the heavily doped SiC layer 20 also includes a plurality of grooves, and variation trends of dimensions related to the plurality of grooves of the heavily doped SiC layer 20 also exhibit the periodic changes described above. The widths of the plurality of grooves and the spacing distances between adjacent grooves in the plurality of grooves are changed, so that current distribution may be effectively regulated, improving uniformity of the current distribution.

Optionally, regardless of the plurality of grooves of the SiC substrate 10 or the plurality of grooves of the heavily doped SiC layer 20, a variation trend of dimensions related to the plurality of grooves may also include at least one of the followings: widths of the plurality of grooves first gradually increasing and then gradually decreasing or spacing distances between adjacent grooves in the plurality of grooves first increasing and then gradually decreasing, and at this time, the dimensions related to the plurality of grooves increase from both sides to a middle; and a variation trend of dimensions related to the plurality of grooves may also include at least one of the followings: widths of the plurality of grooves first gradually decreasing and then gradually increasing or spacing distances between adjacent grooves in the plurality of grooves first decreasing and then gradually increasing, and at this time, the dimensions related to the plurality of grooves decrease from both sides to a middle. The variation trend of dimensions related to the plurality of grooves is not specifically limited by the present disclosure, as long as the current distribution can be effectively regulated and the uniformity of the current distribution can be improved.

In an embodiment, FIG. 4 is a schematic structural diagram of a semiconductor structure according to an embodiment of the present disclosure. As shown in FIG. 4, the SiC substrate 10 is a flat substrate, and the heavily doped SiC layer 20 is a patterned SiC layer, which may also increase a contact area between the heavily doped SiC layer 20 and the AlGaN epitaxial layer 30, reducing on-resistance of an interface, and further achieving a low turn-on voltage.

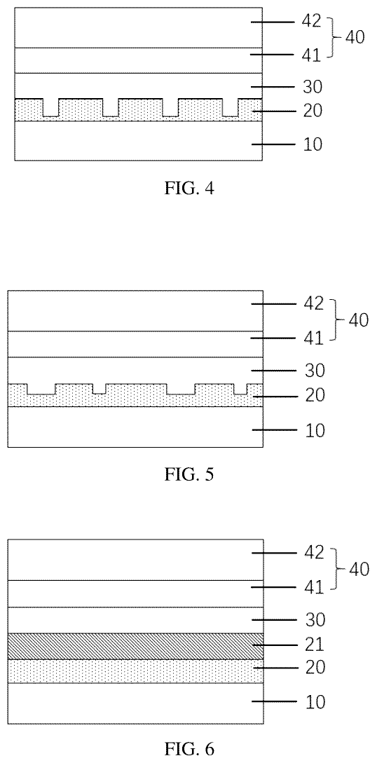

Optionally, FIG. 5 is a schematic structural diagram of a semiconductor structure according to an embodiment of the present disclosure, and as shown in FIG. 5, on a side, away from the SiC substrate 10, of the heavily doped SiC layer 20, the heavily doped SiC layer 20 includes a plurality of pits partially penetrating the heavily doped SiC layer 20. A variation trend of dimensions related to the plurality of pits may include at least one of the followings: a periodic change in widths of the plurality of pits or a periodic change in spacing distances between adjacent pits in the plurality of pits. The widths of the plurality of pits and the spacing distances between adjacent pits in the plurality of pits are changed, so that current distribution may be effectively regulated, improving uniformity of the current distribution.

Optionally, a variation trend of dimensions related to the plurality of pits may also include at least one of the followings: widths of the plurality of pits first gradually increasing and then gradually decreasing or spacing distances between adjacent pits in the plurality of pits first increasing and then gradually decreasing, and at this time, the dimensions related to the plurality of pits increase from both sides to a middle; and a variation trend of dimensions related to the plurality of pits may also include at least one of the followings: widths of the plurality of pits first gradually decreasing and then gradually increasing or spacing distances between adjacent pits in the plurality of pits first decreasing and then gradually increasing, and at this time, the dimensions related to the plurality of pits decrease from both sides to a middle. The variation trend of dimensions related to the plurality of pits is not specifically limited by the present disclosure, as long as the current distribution can be effectively regulated and the uniformity of the current distribution can be improved.

In an embodiment, FIG. 6 is a schematic structural diagram of a semiconductor structure according to an embodiment of the present disclosure. As shown in FIG. 6, the semiconductor structure further includes: a first insertion layer 21 located between the heavily doped SiC layer 20 and the AlGaN epitaxial layer 30. The first insertion layer 21 is of a second conductivity type, and a material of the first insertion layer 21 includes SiC. Since a material of the AlGaN epitaxial layer 30 is AlGaN and a material of the heavily doped SiC layer 20 is SiC, a lattice constant difference between the material of the first insertion layer 21 and the material of the AlGaN epitaxial layer 30 located above the first insertion layer 21, and a lattice constant difference between the material of the first insertion layer 21 and the material of the heavily doped SiC layer 20 located below the first insertion layer 21 are relatively small. The first insertion layer 21 has a buffering effect, and a doping concentration of an ion with the second conductivity type and in the first insertion layer 21 is greater than or equal to 1E18/cm³. Optionally, the first conductivity type is n-type and the second conductivity type is p-type. An nSiC/pSiC tunnel junction is formed by the n-type heavily doped SiC layer 20 and the p-type first insertion layer 21, and therefore, flow of charges may be effectively blocked by utilizing a tunnel mechanism to realize a normally-off characteristic of a semiconductor structure, which is beneficial for improving a threshold voltage and reducing a reverse leakage current.

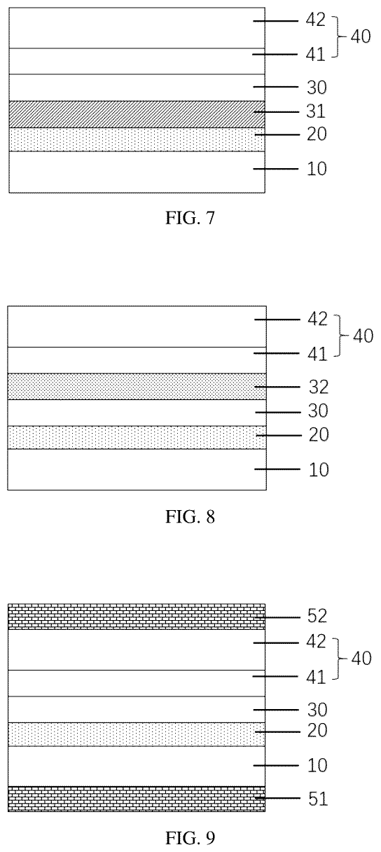

In an embodiment, FIG. 7 is a schematic structural diagram of a semiconductor structure according to an embodiment of the present disclosure. As shown in FIG. 7, the semiconductor structure further includes: a second insertion layer 31 located between the heavily doped SiC layer 20 and the AlGaN epitaxial layer 30. The second insertion layer 31 is of a second conductivity type, and a material of the second insertion layer 31 includes AlGaN. A doping concentration of an ion with the second conductivity type and in the second insertion layer 31 is greater than or equal to 1E18/cm³. Optionally, the first conductivity type is n-type and the second conductivity type is p-type. A pAlGaN/nAlGaN tunnel junction is also formed by the p-type second insertion layer 31 and the n-type AlGaN epitaxial layer 30, and therefore, flow of charges may be effectively blocked by utilizing a tunnel mechanism to realize a normally-off characteristic of a semiconductor structure, which is beneficial for improving a threshold voltage and reducing a reverse leakage current. Optionally, an Al component of the second insertion layer 31 decreases successively along a direction from the SiC substrate 10 to the GaN epitaxial layer 40, reducing a lattice difference between the heavily doped SiC layer 20 and the AlGaN epitaxial layer 30, and further making the second insertion layer 31 have a buffering effect.

In an embodiment, FIG. 8 is a schematic structural diagram of a semiconductor structure according to an embodiment of the present disclosure. As shown in FIG. 8, the semiconductor structure further includes: a third insertion layer 32 located between the AlGaN epitaxial layer 30 and the GaN epitaxial layer 40. The third insertion layer 32 is of a second conductivity type, and a material of the third insertion layer 32 includes AlGaN. A doping concentration of an ion with the second conductivity type and in the third insertion layer 32 is greater than or equal to 1E18/cm³. Optionally, the first conductivity type is n-type and the second conductivity type is p-type. An nAlGaN/pAlGaN tunnel junction is formed by the n-type AlGaN epitaxial layer 30 and the p-type third insertion layer 32, and therefore, flow of charges may be effectively blocked by utilizing a tunnel mechanism to realize a normally-off characteristic of a semiconductor structure, which is beneficial for improving a threshold voltage and reducing a reverse leakage current. Optionally, an Al component of the third insertion layer 32 decreases successively along a direction from the SiC substrate 10 to the GaN epitaxial layer 40, reducing a lattice difference between the AlGaN epitaxial layer 30 and the GaN epitaxial layer 40, and further making the third insertion layer 32 have a buffering effect.

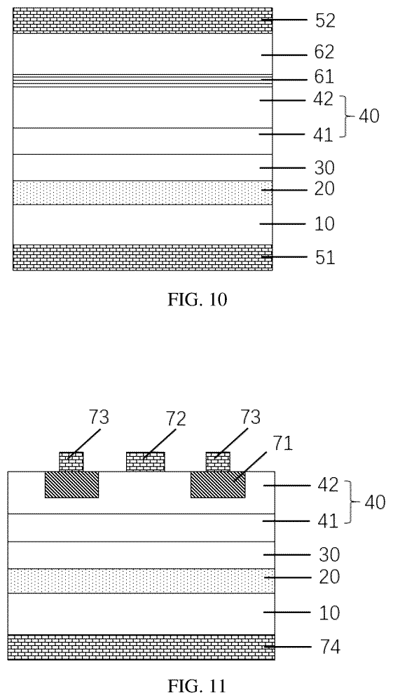

According to another aspect of the present disclosure, the present disclosure provides a semiconductor device. FIG. 9 to FIG. 11 are schematic structural diagrams of semiconductor devices according to some embodiments of the present disclosure. The semiconductor device includes the semiconductor structure described above, and the semiconductor device is any one of a Schottky diode, a Positive-Intrinsicnegative (PIN) diode or a junction field-effect transistor. As shown in FIG. 9, in a case that the semiconductor device is the Schottky diode, the semiconductor device includes the semiconductor structure described above, as well as a first electrode 51 and a second electrode 52. The first electrode 51 is located on a side, away from the GaN epitaxial layer 40, of the SiC substrate 10, and the second electrode 52 is located on a side, away from the SiC substrate 10, of the GaN epitaxial layer 40. As shown in FIG. 10, in a case that the semiconductor device is the PIN diode, the semiconductor device includes the semiconductor structure described above, an intrinsic semiconductor layer 61, a second conductivity type semiconductor layer 62, and a second electrode 52 that are stacked sequentially on the GaN epitaxial layer 40, and a first electrode 51 located on a side, away from the GaN epitaxial layer 40, of the SiC substrate 10. As shown in FIG. 11, in a case that the semiconductor device is the junction field-effect transistor, the semiconductor device includes the semiconductor structure described above, a p-type region 71 located within a surface, away from the SiC substrate 10, of the GaN epitaxial layer 40, a source 72 located on a side, away from the SiC substrate 10, of the GaN epitaxial layer 40, a grid 73 located on a side, away from the SiC substrate 10, of the p-type region 71, and a drain 74 located on a side, away from the GaN epitaxial layer 40, of the SiC substrate 10. The semiconductor device provided by the present disclosure has a low turn-on voltage, a high threshold voltage, a low reverse leakage current, as well as high-quality and high-reliability.

The present disclosure provides a semiconductor structure and a semiconductor device. The semiconductor structure includes a SiC substrate, a heavily doped SiC layer, an AlGaN epitaxial layer, and a GaN epitaxial layer that are stacked sequentially. The GaN epitaxial layer includes a heavily doped layer and a lightly doped layer that are stacked. The SiC substrate, the heavily doped SiC layer, the AlGaN epitaxial layer, and the GaN epitaxial layer are all of a first conductivity type. On the one hand, design of the heavily doped SiC layer in the present disclosure is conducive to reducing on-resistance, so as to achieve a low turn-on voltage. Design of the patterned heavily doped SiC layer may further increase a contact area, so as to reduce on-resistance of an interface. On the other hand, a tunnel junction is formed by an insertion layer designed in the present disclosure and one of the heavily doped SiC layer and the AlGaN epitaxial layer, and therefore, flow of charges may be effectively blocked by utilizing a tunnel mechanism to realize a normally-off characteristic of a semiconductor structure, which is beneficial for improving a threshold voltage and reducing a reverse leakage current. Design of the insertion layers in different epitaxial layers may regulate and control a position of the tunnel junction in a semiconductor structure, so as to further regulate a threshold voltage.

It should be understood that the term “including” and its variations used in the present disclosure are open-ended, i.e., “including but not limited to”. The term “an embodiment” means “at least one embodiment”; and the term “another embodiment” means “at least one another embodiment”. In this specification, schematic representations of the above terms do not necessarily refer to the same example or embodiment. Moreover, the specific features, structures, materials, or characteristics described herein may be combined in any suitable manner in any one or more of the examples or embodiments. Furthermore, without conflicting with each other, a person of ordinary skill in the art may combine and integrate different examples or embodiments described herein, as well as features of the different examples or embodiments.

The above are only preferred embodiments of the present disclosure and are not intended to limit the present disclosure. Any modifications, equivalent substitutions, etc. made within the spirit and principles of the present disclosure shall be included within the scope of protection of the present disclosure.

What is claimed is:

1. A semiconductor structure, comprising:
a SiC substrate, a heavily doped SiC layer, an AlGaN epitaxial layer, and a GaN epitaxial layer that are stacked sequentially, wherein the GaN epitaxial layer comprises a heavily doped layer and a lightly doped layer that are stacked, and the SiC substrate, the heavily doped SiC layer, the AlGaN epitaxial layer, and the GaN epitaxial layer are all of a first conductivity type.

2. The semiconductor structure according to claim 1, wherein the SiC substrate is a patterned substrate.

3. The semiconductor structure according to claim 2, wherein on a side, close to the heavily doped SiC layer, of the SiC substrate, the SiC substrate comprises a plurality of grooves partially penetrating the SiC substrate, and a variation trend of dimensions related to the plurality of grooves comprises at least one of the followings: a periodic change in widths of the plurality of grooves or a periodic change in spacing distances between adjacent grooves in the plurality of grooves.

4. The semiconductor structure according to claim 2, wherein on a side, close to the heavily doped SiC layer, of the SiC substrate, the SiC substrate comprises a plurality of grooves partially penetrating the SiC substrate;
a variation trend of dimensions related to the plurality of grooves comprises at least one of the followings: widths of the plurality of grooves first gradually increasing and then gradually decreasing or spacing distances between adjacent grooves in the plurality of grooves first increasing and then gradually decreasing, and the dimensions related to the plurality of grooves increase from both sides to a middle, or
a variation trend of dimensions related to the plurality of grooves comprises at least one of the followings: widths of the plurality of grooves first gradually decreasing and then gradually increasing or spacing distances between adjacent grooves in the plurality of grooves first decreasing and then gradually increasing, and the dimensions related to the plurality of grooves decrease from both sides to a middle.

5. The semiconductor structure according to claim 2, wherein the heavily doped SiC layer is conformally located on the SiC substrate.

6. The semiconductor structure according to claim 1, wherein the heavily doped SiC layer is a patterned SiC layer, and on a side, away from the SiC substrate, of the heavily doped SiC layer, the heavily doped SiC layer comprises a plurality of pits partially penetrating the heavily doped SiC layer.

7. The semiconductor structure according to claim 6, wherein a variation trend of dimensions related to the plurality of pits comprises at least one of the followings: a periodic change in widths of the plurality of pits or a periodic change in spacing distances between adjacent pits in the plurality of pits.

8. The semiconductor structure according to claim 6, wherein a variation trend of dimensions related to the plurality of pits comprises at least one of the followings: widths of the plurality of pits first gradually increasing and then gradually decreasing or spacing distances between adjacent pits in the plurality of pits first increasing and then gradually decreasing, and the dimensions related to the plurality of pits increase from both sides to a middle, or
a variation trend of dimensions related to the plurality of pits comprises at least one of the followings: widths of the plurality of pits first gradually decreasing and then gradually increasing or spacing distances between adjacent pits in the plurality of pits first decreasing and then gradually increasing, and the dimensions related to the plurality of pits decrease from both sides to a middle.

9. The semiconductor structure according to claim 1, further comprising:
a first insertion layer located between the heavily doped SiC layer and the AlGaN epitaxial layer, wherein the first insertion layer is of a second conductivity type, and a tunnel junction is formed by the first insertion layer and the heavily doped SiC layer.

10. The semiconductor structure according to claim 9, wherein a material of the first insertion layer comprises SiC, and an nSiC/pSiC tunnel junction is formed by the heavily doped SiC layer and the first insertion layer.

11. The semiconductor structure according to claim 1, further comprising:
a second insertion layer located between the heavily doped SiC layer and the AlGaN epitaxial layer, wherein the second insertion layer is of a second conductivity type, and a tunnel junction is formed by the second insertion layer and the AlGaN epitaxial layer.

12. The semiconductor structure according to claim 11, wherein a material of the second insertion layer comprises AlGaN, and a pAlGaN/nAlGaN tunnel junction is formed by the second insertion layer and the AlGaN epitaxial layer.

13. The semiconductor structure according to claim 12, wherein an Al component of the second insertion layer decreases successively along a direction from the SiC substrate to the GaN epitaxial layer.

14. The semiconductor structure according to claim 1, further comprising:
a third insertion layer located between the AlGaN epitaxial layer and the GaN epitaxial layer, wherein the third insertion layer is of a second conductivity type, and a tunnel junction is formed by the third insertion layer and the AlGaN epitaxial layer.

15. The semiconductor structure according to claim 14, wherein a material of the third insertion layer comprises AlGaN, and an nAlGaN/pAlGaN tunnel junction is formed by the AlGaN epitaxial layer and the third insertion layer.

16. The semiconductor structure according to claim 15, wherein an Al component of the third insertion layer decreases successively along a direction from the SiC substrate to the GaN epitaxial layer.

17. A semiconductor device, comprising:
a semiconductor structure, wherein the semiconductor device is any one of a Schottky diode, a Positive-Intrinsicnegative (PIN) diode, or a junction field-effect transistor;
the semiconductor structure comprises: a SiC substrate, a heavily doped SiC layer, an AlGaN epitaxial layer, and a GaN epitaxial layer that are stacked sequentially, the GaN epitaxial layer comprises a heavily doped layer and a lightly doped layer that are stacked, and the SiC substrate, the heavily doped SiC layer, the AlGaN epitaxial layer, and the GaN epitaxial layer are all of a first conductivity type.

18. The semiconductor device according to claim 17, wherein in a case that the semiconductor device is the Schottky diode, the semiconductor device further comprises a first electrode located on a side, away from the GaN epitaxial layer, of the SiC substrate and a second electrode located on a side, away from the SiC substrate, of the GaN epitaxial layer.

19. The semiconductor device according to claim 17, wherein in a case that the semiconductor device is the PIN diode, the semiconductor device further comprises an intrinsic semiconductor layer, a second conductivity type semiconductor layer, a second electrode that are stacked sequentially on the GaN epitaxial layer, and a first electrode located on a side, away from the GaN epitaxial layer, of the SiC substrate.

20. The semiconductor device according to claim 17, wherein in a case that the semiconductor device is the junction field-effect transistor, the semiconductor device further comprises a p-type region located within a surface, away from the SiC substrate, of the GaN epitaxial layer, a source located on a side, away from the SiC substrate, of the GaN epitaxial layer, a grid located on a side, away from the SiC substrate, of the p-type region, and a drain located on a side, away from the GaN epitaxial layer, of the SiC substrate.
